(19) United States
(12) Patent Application Publication
(10) Pub. No.: US 2025/0248162 A1
(43) Pub. Date: Jul. 31, 2025

(54) IMAGE SENSOR

(71) Applicant: Samsung Electronics Co., Ltd., Suwon-si (KR)

(72) Inventors: Jihyun KWAK, Suwon-si (KR); JONGHYUN GO, Suwon-si (KR); MINKWAN KIM, Suwon-si (KR); Taemin KIM, Suwon-si (KR); CHANG KYU LEE, Suwon-si (KR); MINHO JANG, Suwon-si (KR)

(21) Appl. No.: 19/013,468

(22) Filed: Jan. 8, 2025

(30) Foreign Application Priority Data
Jan. 26, 2024 (KR) 10-2024-0012451
Jul. 19, 2024 (KR) 10-2024-0095524

(51) Int. Cl. H10F 39/00

(52) U.S. Cl. CPC H10F 39/811; H10F 39/8063

(57) ABSTRACT

An image sensor includes a pad overlapping a pad zone of a substrate, and a conductive structure surrounding the pad. The conductive structure includes a conductive layer contacting a bottom surface of the pad, and a conductive via extending from a bottom surface of the conductive layer toward a bottom surface of the substrate. The conductive layer and the conductive via have the same material. A bottom surface of the conductive via is closer to a bottom surface of the substrate than the bottom surface of the conductive layer. The bottom surface of the pad and the bottom surface of the conductive layer are between the bottom surface of the substrate and a top surface of the substrate.

### CROSS-REFERENCE TO RELATED APPLICATIONS

This U.S. nonprovisional application claims priority under 35 U.S.C § 119 to Korean Patent Applications No. 10-2024-0012451 filed on Jan. 26, 2024 and No. 10-2024-0095524 filed Jul. 19, 2024 in the Korean Intellectual Property Office, the disclosures of which are hereby incorporated by reference in their entirety.

### BACKGROUND

The present inventive concepts relate to an image sensor, and more particularly, to an image sensor including a conductive layer.

An image sensor is a device to convert optical images into electrical signals. An image sensor can be classified into a charge coupled device (CCD) type and a complementary metal oxide semiconductor (CMOS) type. A CMOS type image sensor is abbreviated to CIS (CMOS image sensor). The CIS has a plurality of two-dimensionally arranged pixels. Each of the pixels includes a photodiode. The photodiode serves to convert incident light into electrical signals.

### SUMMARY

Some embodiments of the present inventive concepts provide an image sensor whose electrical properties are improved.

According to an aspect of the present disclosure, an image sensor includes a substrate with a pixel array zone and a pad zone, a microlens overlapping the pixel array zone, a pad overlapping the pad zone, and a conductive structure surrounding the pad. The conductive structure includes a conductive layer contacting a bottom surface of the pad, and a conductive via extending from a bottom surface of the conductive layer toward a bottom surface of the substrate. A material of the conductive layer is the same as a material of the conductive via. A distance between the bottom surface of the substrate and a bottom surface of the conductive via is less than a distance between the bottom surface of the substrate and the bottom surface of the conductive layer. The distance between the bottom surface of the substrate and the bottom surface of the conductive layer is less than a distance between the bottom surface of the substrate and the bottom surface of the pad. The bottom surface of the pad and the bottom surface of the conductive layer are between the bottom surface of the substrate and a top surface of the substrate.

According to an aspect of the present disclosure, an image sensor includes a substrate that includes a pixel array zone and a pad zone, a microlens that overlaps the pixel array zone, a pad that overlaps the pad zone, a conductive structure that surrounds the pad, and a first connection conductive structure electrically connected to the conductive structure. The conductive structure includes a conductive layer in contact with a bottom surface of the pad, and a conductive via that extends from a bottom surface of the conductive layer toward a bottom surface of the substrate. A bottom surface of the conductive via is in contact with a top surface of the first connection conductive structure. A sidewall of the conductive via is in contact with the substrate.

According to an aspect of the present disclosure, an image sensor includes a first substrate that includes a pixel array zone and a pad zone, wherein the pixel array zone includes a photoelectric conversion region, a color filter that overlaps the photoelectric conversion region, a lens layer on the color filter, a pad that overlaps the pad zone, a conductive structure that surrounds the pad, a second substrate spaced apart from the first substrate, a first dielectric structure and a second dielectric structure that are in contact with each other between the first substrate and the second substrate, a first bonding pad in the first dielectric structure, a second bonding pad in the second dielectric structure and in contact with the first bonding pad, and a first connection conductive structure and a second connection conductive structure that electrically connect the conductive layer to the first bonding pad. The conductive structure includes a conductive layer in contact with a bottom surface of the pad, and a conductive via between the conductive layer and the first connection conductive structure. A material of the conductive layer is the same as a material of the conductive via. The second connection conductive structure is surrounded by the first dielectric structure. The first connection conductive structure includes a first part surrounded by the first substrate, and a second part surrounded by the first dielectric structure.

### BRIEF DESCRIPTION OF DRAWINGS

FIG. 1 illustrates a block diagram showing an image sensor according to some embodiments.

FIG. 2 illustrates a circuit diagram showing an active pixel sensor array of an image sensor according to some embodiments.

FIG. 3A illustrates a plan view showing an image sensor according to some embodiments.

FIG. 3B illustrates a cross-sectional view taken along line A-A′ of FIG. 3A.

FIG. 3C illustrates a cross-sectional view taken along line B-B′ of FIG. 3A.

FIG. 3D illustrates an enlarged view showing section E of FIG. 3C.

FIGS. 4A, 4B, 4C, 5, and 6 illustrate diagrams showing a method of fabricating an image sensor depicted in FIGS. 3A to 3D.

FIG. 7 illustrates an enlarged cross-sectional view showing an image sensor according to some embodiments.

FIG. 8 illustrates an enlarged cross-sectional view showing an image sensor according to some embodiments.

FIG. 9 illustrates an enlarged cross-sectional view showing an image sensor according to some embodiments.

FIG. 10 illustrates an enlarged cross-sectional view showing an image sensor according to some embodiments.

FIG. 11 illustrates a plan view showing a conductive layer and connection conductive structures of an image sensor according to some embodiments.

FIGS. 12A and 12B illustrate cross-sectional views showing an image sensor according to some embodiments.

FIG. 13 illustrates an enlarged cross-sectional view showing an image sensor according to some embodiments.

FIGS. 14A and 14B illustrate cross-sectional views showing an image sensor according to some embodiments.

### DETAILED DESCRIPTION OF EMBODIMENTS

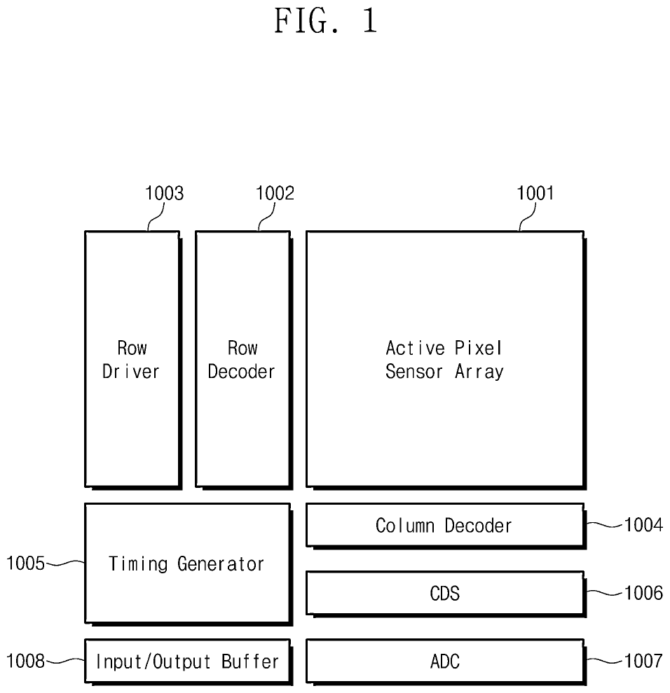

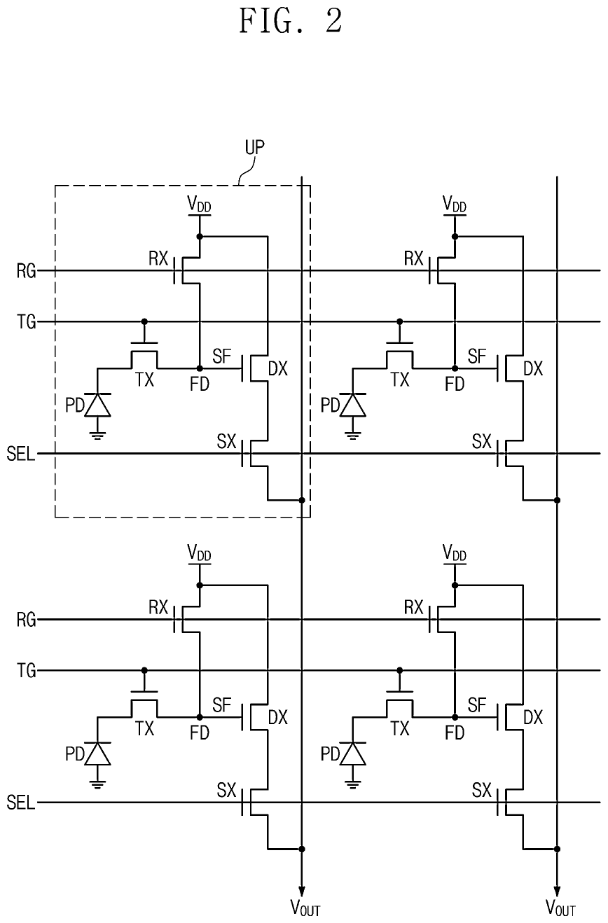

FIG. 1 illustrates a block diagram showing an image sensor according to some embodiments. FIG. 2 illustrates a circuit diagram showing an active pixel sensor array of an image sensor according to some embodiments.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of two-dimensionally arranged unit pixels, each of which is configured to convert optical signals into electrical signals. The active pixel sensor array 1001 may be driven by a plurality of driving signals such as a pixel selection signal, a reset signal, and a charge transfer signal from the row driver 1003. The correlated double sampler 1006 may be provided with the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for each row.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise level and signal level.

The analog-to-digital converter 1007 may convert analog signals, which correspond to the difference level received from the correlated double sampler 1006, into digital signals, and then output the converted digital signals.

The input/output buffer 1008 may latch the digital signals and then sequentially output the latched digital signals to an image signal processing unit (not shown) in response to the decoded result obtained from the column decoder 1004.

Referring to FIGS. 1 and 2, the active pixel sensor array 1001 may include a plurality of unit pixels UP, which may be arranged in a matrix shape. Each unit pixel UP may include a transfer transistor TX. Each unit pixel UP may further include logic transistors RX, SX, and DX. The logic transistors RX, SX, and DX may include a reset transistor RX, a selection transistor SX, and a source follower transistor DX. The transfer transistor TX may include a transfer gate TG. Each unit pixel UP may further include a photoelectric conversion region PD and a floating diffusion region FD. The present disclosure is not limited thereto. In some embodiments, the logic transistors RX, SX, and DX may be shared by a plurality of unit pixels UP.

The photoelectric conversion region PD may create and accumulate photo-charges in proportion to an amount of externally incident light. The photoelectric conversion region PD may include a photodiode, phototransistor, a photogate, a pinned photodiode, or a combination thereof. The transfer transistor TX may transfer charges generated in the photoelectric conversion region PD into the floating diffusion region FD. The floating diffusion region FD may accumulate and store charges that are generated and transferred from the photoelectric conversion region PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage VDD. When the reset transistor RX is turned on, the floating diffusion region FD may be supplied with the power voltage VDD connected to the source electrode of the reset transistor RX. Accordingly, when the reset transistor RX is turned on, the charges accumulated in the floating diffusion region FD may be exhausted (i.e., depleted) and thus the floating diffusion region FD may be reset.

The source follower transistor DX including a source follower gate SF may serve as a source follower buffer amplifier. The source follower transistor DX may amplify a variation in electrical potential of the floating diffusion region FD and may output the amplified electrical potential to an output line VOUT.

The selection transistor SX including a selection gate electrode SEL may select each row of the unit pixel UP to be readout. When the selection transistor SX is turned on, the power voltage VDD may be applied to a drain electrode of the source follower transistor DX.

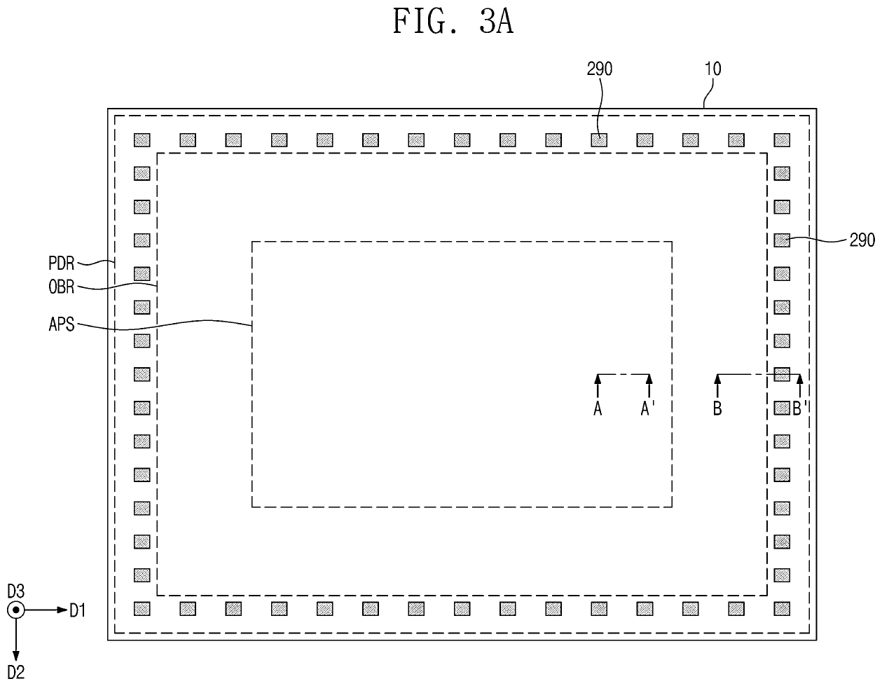

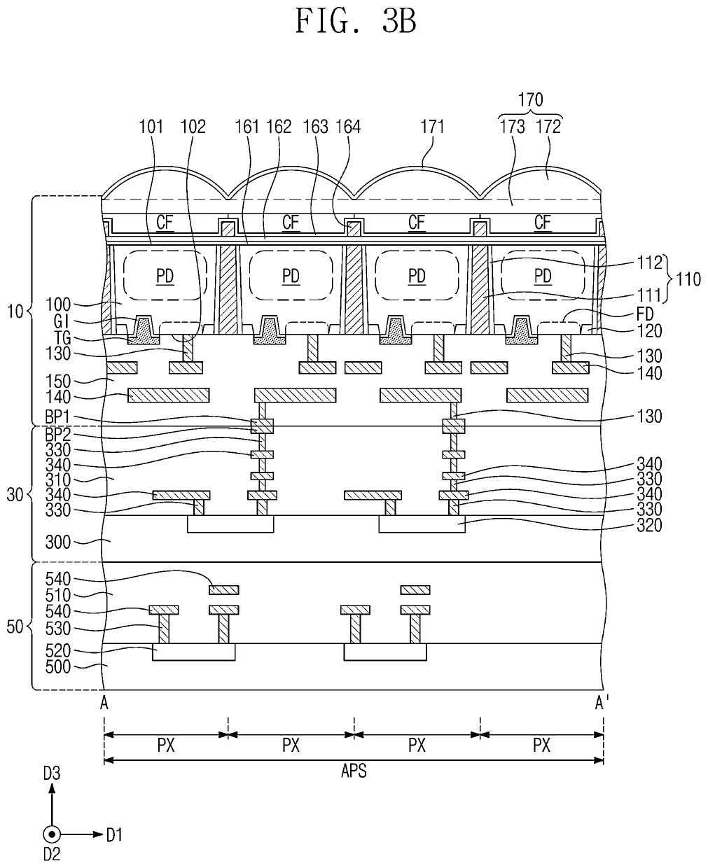

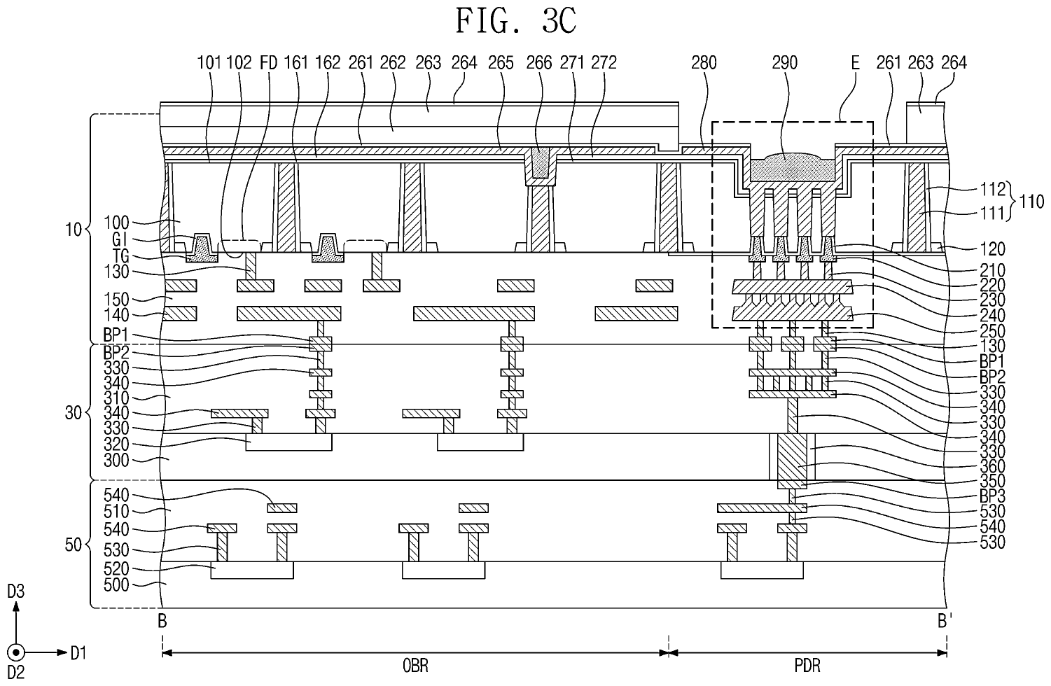

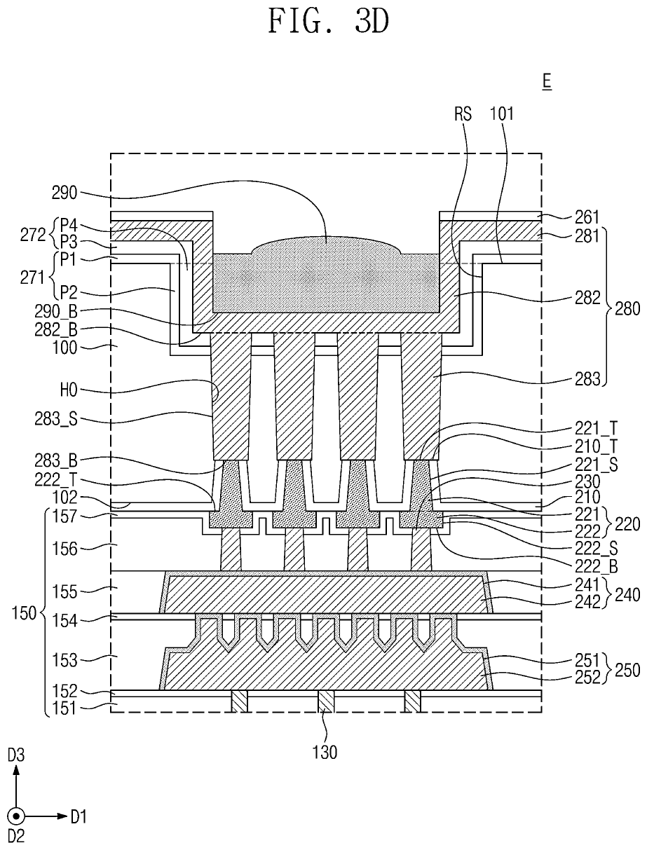

FIG. 3A illustrates a plan view showing an image sensor according to some embodiments. FIG. 3B illustrates a cross-sectional view taken along line A-A′ of FIG. 3A. FIG. 3C illustrates a cross-sectional view taken along line B-B′ of FIG. 3A. FIG. 3D illustrates an enlarged view showing section E of FIG. 3C.

Referring to FIGS. 3A to 3C, an image sensor may include a sensor chip 10. The sensor chip 10 may include a first substrate 100. The first substrate 100 may have a plate shape that extends along a plane defined by a first direction D1 and a second direction D2. The first direction D1 and the second direction D2 may intersect each other. For example, the first direction D1 and the second direction D2 may be horizontal directions orthogonal to each other. In an embodiment, the first and second directions D1 and D2 may be parallel to an upper surface of the first substrate 100.

The first substrate 100 may be a semiconductor substrate. For example, the first substrate 100 may be a silicon substrate, a germanium substrate, or a silicon-germanium substrate. The first substrate 100 may include impurities of a first conductivity type. For example, the first substrate 100 may include P-type impurities such as aluminum (Al), boron (B), indium (In), and gallium (Ga). In some embodiments, the first substrate 100 may be a silicon-on-insulator (SOI) substrate.

The first substrate 100 may include a pixel array zone APS, an optical black zone OBR, and a pad zone PDR. The pixel array zone APS, the optical black zone OBR, and the pad zone PDR may be areas distinguished on a plane defined by the first direction D1 and the second direction D2. The optical black zone OBR may surround the pixel array zone APS, and the pad zone PDR may surround the optical black zone OBR and the pixel array zone APS.

The first substrate 100 may have a bottom surface 102 and a top surface 101 that are opposite to each other. The top surface 101 of the first substrate 100 may receive incident light.

The pixel array zone APS of the first substrate 100 may include a plurality of pixel sections PX. The pixel section PX of the pixel array zone APS may output photoelectric signals from incident light. The pixel sections PX may be two-dimensionally arranged on the pixel array zone APS. In an embodiment, each pixel section PX may corresponds to a unit pixel.

The pixel array zone APS of the first substrate 100 may include a plurality of photoelectric conversion regions PD. The photoelectric conversion regions PD may be disposed between the top surface 101 and the bottom surface 102 of the first substrate 100. The photoelectric conversion regions PD may be correspondingly provided in the pixel sections PX of the first substrate 100.

The photoelectric conversion region PD may include impurities of a second conductivity type. The second conductivity type may be different from the first conductivity type. For example, the photoelectric conversion region PD may include phosphorus, arsenic, bismuth, or antimony as the second conductivity type impurities. The photoelectric conversion region PD may be adjacent to the top surface 101 of the first substrate 100.

The first substrate 100 may include a plurality of floating diffusion regions FD. The floating diffusion regions FD may be correspondingly provided in the pixel sections PX of the first substrate 100. The floating diffusion regions FD may include impurities of the second conductivity type. The floating diffusion region FD may be adjacent to the bottom surface 102 of the first substrate 100.

The sensor chip 10 may include a pixel isolation pattern 110. The pixel isolation pattern 110 may be provided in the first substrate 100. The pixel isolation pattern 110 may extend in a third direction D3 to penetrate the first substrate 100. The third direction D3 may intersect the first direction D1 and the second direction D2. For example, the third direction D3 may be a vertical direction perpendicular to the first direction D1 and the second direction D2. In an embodiment, the third direction D3 may be perpendicular to the upper surface of the first substrate 100. The pixel isolation pattern 110 may define the pixel sections PX. The pixel isolation pattern 110, when viewed in a plan view, may have, for example, a grid shape.

The pixel isolation pattern 110 may include an isolation conductive layer 111 and an isolation dielectric layer 112. The isolation conductive layer 111 may penetrate the first substrate 100. The isolation dielectric layer 112 may be interposed between the isolation conductive layer 111 and the first substrate 100. The isolation conductive layer 111 may include a conductive material. The isolation dielectric layer 112 may include a dielectric material.

The sensor chip 10 may include a device isolation pattern 120. The device isolation pattern 120 may be provided in the first substrate 100. The device isolation pattern 120 may be disposed adjacent to the bottom surface 102 of the first substrate 100. The device isolation pattern 120 may define an active region of the first substrate 100. The device isolation pattern 120 may include a dielectric material.

The sensor chip 10 may include a first dielectric structure 150 that covers the bottom surface 102 of the first substrate 100. The first dielectric structure 150 may cover the active region of the first substrate 100. The first dielectric structure 150 may include a dielectric material. In some embodiments, the first dielectric structure 150 may be a multi-layered structure including a plurality of dielectric layers.

The sensor chip 10 may include transfer gates TG and gate dielectric layers GI. The transfer gate TG may be provided between the first substrate 100 and the first dielectric structure 150. The transfer gate TG and the gate dielectric layer GI may penetrate the bottom surface 102 of the first substrate 100. The transfer gate TG may include a conductive material. For example, the transfer gate TG may include polysilicon doped with boron (B), arsenic (As), or phosphorus (P). The gate dielectric layer GI may be provided between the transfer gate TG and the first substrate 100. The gate dielectric layer GI may include a dielectric material.

The first dielectric structure 150 may be provided therein with first contacts 130, first conductive lines 140, and first bonding pads BP1. At least one of the first contacts 130 may be connected to the floating diffusion region FD. The first conductive line 140 may be connected to the first contact 130. The first bonding pad BP1 may be connected to the first contact 130. The first contacts 130, the first conductive lines 140, and the first bonding pads BP1 may include a conductive material.

The sensor chip 10 may include a first protective layer 161 on the top surface 101 of the first substrate 100, a fixed charge layer 162 on the first protective layer 161, and a second protective layer 163 on the fixed charge layer 162. The first protective layer 161 and the fixed charge layer 162 may extend from the pixel array zone APS to the optical black zone OBR. The second protective layer 163 may be disposed on the pixel array zone APS. In an embodiment, the first protective layer 161 and the fixed charge layer 162 may be disposed on both the pixel array zone APS and the optical black zone OBR. In an embodiment, the second protective layer 163 may be disposed only on the pixel array zone APS. In other words, the second protective layer 163 may not be disposed on the optical black zone OBR.

The first protective layer 161 and the second protective layer 163 may include a dielectric material. For example, the first protective layer 161 and the second protective layer 163 may include aluminum oxide.

The fixed charge layer 162 may have a negative fixed charge, and may generate a hole accumulation. The fixed charge layer 162 may effectively reduce white spot and dark current of the first substrate 100. In some embodiments, the fixed charge layer 162 may be a multiple layer including a plurality of layers. For example, the fixed charge layer 162 may include a first layer including hafnium oxide, a second layer including silicon oxide, a third layer including silicon nitride, and a fourth layer including hafnium oxide.

The sensor chip 10 may include a fence pattern 164 on the fixed charge layer 162. The fence pattern 164 may be disposed on the pixel array zone APS. The fence pattern 164 may separate subsequently described color filters CF from each other. For example, the fence pattern 164 may have a grid shape. In some embodiments, the fence pattern 164 may be a single metal layer, a single dielectric layer, or a multiple layer including a metal layer and a dielectric layer. The metal layer may include, for example, tungsten. The dielectric layer may include, for example, oxide. In some embodiments, the fence pattern 164 may further include an empty space. The empty space may be provided with, for example, air.

The sensor chip 10 may include a light-shield layer 265 on the fixed charge layer 162. The light-shield layer 265 may be disposed on the optical black zone OBR. The light-shield layer 265 may include a conductive material. In some embodiments, the light-shield layer 265 may include the same material as that of the fence pattern 164. For example, the light-shield layer 265 may include tungsten.

The sensor chip 10 may include a connection contact 266. The connection contact 266 may be disposed on the optical black zone OBR. The connection contact 266 may overlap the pixel isolation pattern 110 in the third direction D3. The connection contact 266 may include a conductive material. For example, the connection contact 266 may include aluminum.

The sensor chip 10 may include pads 290. The pad 290 may be disposed on the pad zone PDR. The pad 290 may overlap the pad zone PDR in the third direction D3. The pad 290 may include a conductive material. For example, the pad 290 may include aluminum.

A conductive structure 280, a first material layer 271, and a second material layer 272 may be provided to separate the pad 290 and the first substrate 100 from each other. At least a portion of each of the conductive structure 280, the first material layer 271, and the second material layer 272 may be provided between the first substrate 100 and the pad 290. The first material layer 271 and the second material layer 272 may extend from the pad zone PDR to the optical black zone OBR. The conductive structure 280 may be provided on the pad zone PDR. In an embodiment, the first material layer 271 and the second material layer 272 may be disposed on both the pixel array zone APS and the optical black zone OBR. In an embodiment, the second conductive structure 280 may be disposed only on the pixel array zone APS. In other words, the second conductive structure 280 may not be disposed on the optical black zone OBR.

In some embodiments, the conductive structure 280 may include the same conductive material as that of the light-shield layer 265. The first material layer 271 and the second material layer 272 may include different dielectric materials from each other. In some embodiments, the first material layer 271 may include the same dielectric material as that of the first protective layer 161. In some embodiments, the second material layer 272 may include the same material as that of the fixed charge layer 162. For example, the second material layer 272 may include a first layer including hafnium oxide, a second layer including silicon oxide, a third layer including silicon nitride, and a fourth layer including hafnium oxide.

The sensor chip 10 may include color filters CF. The color filters CF may be disposed on the pixel array zone APS. The color filter CF may overlap the photoelectric conversion region PD of the pixel array zone APS in the third direction D3. The color filter CF may be disposed on the pixel section PX. Each of the color filters CF may be one of the red, green, and blue filters. The color filters CF may constitute color filter arrays. For example, the color filters CF may be two-dimensionally arranged in Bayer pattern format.

The sensor chip 10 may include a third protective layer 261. The third protective layer 261 may extend from the optical black zone OBR to the pad zone PDR. The third protective layer 261 may be provided on the light-shield layer 265, the connection contact 266, and the conductive structure 280. The third protective layer 261 may separate the light-shield layer 265 and the conductive structure 280 from each other. In some embodiments, the third protective layer 261 may include the same dielectric material as that of the second protective layer 163. For example, the third protective layer 261 may include aluminum oxide.

The sensor chip 10 may include a filtering layer 262 on the third protective layer 261. The filtering layer 262 may be disposed on the optical black zone OBR. The filtering layer 262 may block light whose wavelength is different from that of light produced from the color filters CF.

The sensor chip 10 may include a lens layer 170. The lens layer 170 may be disposed on the pixel array zone APS. The lens layer 170 may be disposed on the color filters CF. The lens layer 170 may be transparent. The lens layer 170 may allow light to pass therethrough. The lens layer 170 may include an organic material. For example, the lens layer 170 may include a photoresist material or a thermosetting resin.

The lens layer 170 may include a base part 173 on the color filters CF and microlenses 172 on the base part 173. The microlenses 172 may protrude in the third direction D3 from the base part 173. The microlenses 172 and the base part 173 may be connected without a boundary. The microlenses 172 and the base part 173 may constitute a single unitary structure.

The microlenses 172 may overlap the pixel array zone APS in the third direction D3. The microlenses 172 may be correspondingly disposed on the pixel sections PX. The microlenses 172 may be provided on positions that correspond to the photoelectric conversion regions PD.

The sensor chip 10 may include a coating layer 171 on the lens layer 170. The coating layer 171 may be transparent. The coating layer 171 may conformally cover a top surface of the lens layer 170.

The sensor chip 10 may include a first cover layer 263 and a second cover layer 264. The first cover layer 263 and the second cover layer 264 may be provided on the optical black zone OBR and the pad zone PDR. The first cover layer 263 may be provided on the filtering layer 262 and the third protective layer 261. The first cover layer 263 may include the same material as that of the lens layer 170.

The second cover layer 264 may be provided on the first cover layer 263. The second cover layer 264 may include the same material as that of the coating layer 171.

The sensor chip 10 may include first connection conductive structures 220 in contact with the conductive structure 280, second connection conductive structures 230 correspondingly in contact with the first connection conductive structures 220, a third connection conductive structure 240 in contact with the second connection conductive structures 230, and a fourth connection conductive structure 250 in contact with the third connection conductive structure 240. The first, second, third, and fourth connection conductive structures 220, 230, 240, and 250 may be sequentially arranged in a direction opposite to the third direction D3. The first, second, third, and fourth connection conductive structures 220, 230, 240, and 250 may include a conductive material. The first, second, third, and fourth connection conductive structures 220, 230, 240, and 250 may be surrounded by the first dielectric structure 150.

The sensor chip 10 may include a first dielectric layer 210 between the first dielectric structure 150 and the first substrate 100. The first dielectric layer 210 may surround the first connection conductive structure 220. The first dielectric layer 210 may include a dielectric material. For example, the first dielectric layer 210 may include oxide such as silicon oxide.

The image sensor may include a sub-chip 30. The sub-chip 30 may include a second substrate 300. The second substrate 300 may be a semiconductor substrate. In some embodiments, the second substrate 300 may be a silicon-on-insulator (SOI) substrate. The second substrate 300 may be spaced apart in the third direction D3 from the first substrate 100.

The sub-chip 30 may include a second dielectric structure 310 on the second substrate 300. The second dielectric structure 310 may cover an active region of the second substrate 300. The second dielectric structure 310 may include a dielectric material. In some embodiments, the second dielectric structure 310 may be a multi-layered structure including a plurality of dielectric layers.

The sub-chip 30 may include first electronic elements 320 between the second substrate 300 and the second dielectric structure 310. The first electronic elements 320 may include at least one selected from a selection transistor, a reset transistor, and a source follower transistor.

The sub-chip 30 may include second contacts 330, second conductive lines 340, and second bonding pads BP2 in the second dielectric structure 310. At least one of the second contacts 330 may be connected to the first electronic element 320. The second conductive lines 340 may be connected to the second contacts 330. The second bonding pads BP2 may be connected to the second contacts 330. The second contacts 330, the second conductive lines 340, and the second bonding pads BP2 may include a conductive material.

The sensor chip 10 may be hybrid bonded to the sub-chip 30. A bottom surface of the first dielectric structure 150 may be in contact with a top surface of the second dielectric structure 310. The first dielectric structure 150 and the second dielectric structure 310 may be disposed between the first substrate 100 and the second substrate 300. A bottom surface of the first bonding pad BP1 may be in contact with a top surface of the second bonding pad BP2.

The sub-chip 30 may further include a spacer 360 and a through via 350. The spacer 360 may be provided in the second substrate 300. The spacer 360 may penetrate in the third direction D3 through the second substrate 300. The spacer 360 may include a dielectric material. For example, the spacer 360 may include silicon oxide or silicon nitride.

The through via 350 may be provided in the spacer 360. The through via 350 may penetrate in the third direction D3 through the second substrate 300 and the spacer 360. The spacer 360 may surround the through via 350. The spacer 360 may separate the through via 350 from the second substrate 300. The through via 350 may include a conductive material. For example, the through via 350 may include copper. The through via 350 may be connected to the second contact 330.

The image sensor may include a circuit chip 50. The circuit chip 50 may include a third substrate 500. The third substrate 500 may be a semiconductor substrate. In some embodiments, the third substrate 500 may be a silicon-on-insulator (SOI) substrate. The third substrate 500 may be spaced apart in the third direction D3 from the second substrate 300.

The circuit chip 50 may include a third dielectric structure 510 on the third substrate 500. The third dielectric structure 510 may cover an active region of the third substrate 500. The third dielectric structure 510 may include a dielectric material. In some embodiments, the third dielectric structure 510 may be a multi-layered structure including a plurality of dielectric layers.

The circuit chip 50 may include second electronic elements 520 between the third substrate 500 and the third dielectric structure 510. The second electronic elements 520 may include at least one selected from an analog-digital converter and a logic circuit.

The circuit chip 50 may include a third bonding pad BP3, third contacts 530 and third conductive lines 540 in the third dielectric structure 510. The third contacts 530 may be connected to the second electronic elements 520. The third bonding pads BP3 may be connected to the through vias 350 and the third contacts 530. A top surface of the third bonding pad BP3 may be in contact with a bottom surface of the through via 350. The third conductive lines 540 may be connected to the third contacts 530. The third contacts 530 and the third conductive lines 540 may include a conductive material.

A top surface of the third dielectric structure 510 may be in contact with a bottom surface of the second substrate 300. The conductive structure 280 may be electrically connected to the second electronic element 520 through the first, second, third, and fourth connection conductive structures 220, 230, 240, and 250, the first contact 130, the first bonding pad BP1, the second bonding pad BP2, the second contact 330, the second conductive line 340, the through via 350, the third bonding pad BP3, the third contact 530, and the third conductive line 540.

Referring to FIG. 3D, the first dielectric structure 150 may include a first interlayer dielectric layer 151, a second interlayer dielectric layer 152 on the first interlayer dielectric layer 151, a third interlayer dielectric layer 153 on the second interlayer dielectric layer 152, a fourth interlayer dielectric layer 154 on the third interlayer dielectric layer 153, a fifth interlayer dielectric layer 155 on the fourth interlayer dielectric layer 154, a sixth interlayer dielectric layer 156 on the fifth interlayer dielectric layer 155, and a second dielectric layer 157 on the sixth interlayer dielectric layer 156. The first to sixth interlayer dielectric layers 151 to 156 and the second dielectric layer 157 may include a dielectric material. The second dielectric layer 157 may include, for example, oxide such as silicon oxide or nitride such as silicon nitride.

The fourth connection conductive structure 250 may penetrate the third interlayer dielectric layer 153 and the fourth interlayer dielectric layer 154. The fourth connection conductive structure 250 may include a barrier layer 251 and a metal layer 252. The barrier layer 251 of the fourth connection conductive structure 250 may be in contact with the third connection conductive structure 240. The metal layer 252 of the fourth connection conductive structure 250 may be in contact with the first contacts 130. The barrier layer 251 of the fourth connection conductive structure 250 may surround the metal layer 252 of the fourth connection conductive structure 250. The barrier layer 251 and the metal layer 252 of the fourth connection conductive structure 250 may include different conductive materials from each other. For example, the metal layer 252 of the fourth connection conductive structure 250 may include copper, and the barrier layer 251 of the fourth connection conductive structure 250 may include titanium.

The fourth connection conductive structure 250 may include one lower part and a plurality of upper parts. The upper parts of the fourth connection conductive structure 250 may be connected to the lower part of the fourth connection conductive structure 250. The upper parts of the fourth connection conductive structure 250 may be in contact with the third connection conductive structure 240. A portion of the third interlayer dielectric layer 153 may be interposed between the upper parts of the fourth connection conductive structure 250. A portion of the fourth interlayer dielectric layer 154 may be interposed between the upper parts of the fourth connection conductive structure 250. The lower part of the fourth connection conductive structure 250 may have a width in the first direction D1 that decreases with decreasing distance from the bottom surface 102 of the first substrate 100.

The third connection conductive structure 240 may penetrate the fifth interlayer dielectric layer 155. The third connection conductive structure 240 may include a barrier layer 241 and a metal layer 242. The barrier layer 241 of the third connection conductive structure 240 may be in contact with the second connection conductive structures 230. The metal layer 242 of the third connection conductive structure 240 may be in contact with the barrier layer 251 of the fourth connection conductive structure 250. The barrier layer 241 of the third connection conductive structure 240 may surround the metal layer 242 of the third connection conductive structure 240. The barrier layer 241 and the metal layer 242 of the third connection conductive structure 240 may include different conductive materials from each other. For example, the metal layer 242 of the third connection conductive structure 240 may include copper, and the barrier layer 241 of the third connection conductive structure 240 may include titanium. The third connection conductive structure 240 may have a width in the first direction D1 that decreases with decreasing distance from the bottom surface 102 of the first substrate 100.

The second connection conductive structures 230 may penetrate the sixth interlayer dielectric layer 156 and the second dielectric layer 157. The second connection conductive structures 230 may be arranged spaced apart from each other in the first direction D1. Bottom surfaces of the second connection conductive structures 230 may be in contact with a top surface of the third connection conductive structure 240. The second connection conductive structures 230 may include a different conductive material from that of the third connection conductive structure 240. For example, the second connection conductive structures 230 may include tungsten.

A width in the first direction D1 of the second connection conductive structure 230 may decrease with decreasing distance from the bottom surface 102 of the first substrate 100. The width in the first direction D1 of the second connection conductive structure 230 may be less than a width in the first direction D1 of the third connection conductive structure 240.

The first connection conductive structures 220 may be arranged spaced apart from each other in the first direction D1. The first connection conductive structures 220 may penetrate the bottom surface 102 of the first substrate 100. The first connection conductive structure 220 may include a part located at a lower level than that of the bottom surface 102 of the first substrate 100 and a part located at a higher level than that of the bottom surface 102 of the first substrate 100. The first connection conductive structure 220 may overlap the second connection conductive structure 230 in the third direction D3. A width in the first direction D1 of the first connection conductive structure 220 may be less than the width in the first direction D1 of the third connection conductive structure 240. In some embodiments, the first connection conductive structure 220 may include the same conductive material as that of the second connection conductive structure 230. For example, the first and second connection conductive structures 220 and 230 may include tungsten. In some embodiments, the first connection conductive structure 220 may include a different conductive material from that of the second connection conductive structure 230. For example, the first connection conductive structure 220 may include polysilicon doped with boron (B), arsenic (As), or phosphorus (P), and the second connection conductive structure 230 may include tungsten. In some embodiments, the first connection conductive structure 220 may include the same conductive material as that of the transfer gate TG.

The first connection conductive structure 220 may include a first part 222 and a second part 221 on the first part 222. A width in the first direction D1 of the first part 222 included in the first connection conductive structure 220 may be greater than a width in the first direction D1 of the second part 221 included in the first connection conductive structure 220. The width in the first direction D1 of the second part 221 included in the first connection conductive structure 220 may decrease with decreasing distance from a bottom surface 283_B of a third conductive part 283 which will be discussed below.

The second dielectric layer 157 may be in contact with a sidewall 222_S and a bottom surface 222_B of the first part 222 included in the first connection conductive structure 220. The first dielectric layer 210 may be in contact with a sidewall 221_B of the second part 221 included in the first connection conductive structure 220 and with a top surface 222_T of the first part 222 included in the first connection conductive structure 220. The first dielectric layer 210 may be in contact with the bottom surface 102 of the first substrate 100. A top surface 210_T of the first dielectric layer 210 may be in contact with the bottom surface 283_B of the third conductive part 283. In some embodiments, the first dielectric layer 210 may be spaced apart from the bottom surface 283_B of the third conductive part 283, and at least a portion of the sidewall 221_S of the second part 221 in the first connection conductive structure 220 may be in contact with the first substrate 100. A top surface 221_T of the second part 221 included in the first connection conductive structure 220 may be in contact with the bottom surface 283_B of the third conductive part 283. A width in the first direction D1 of the top surface 221_T of the second part 221 included in the first connection conductive structure 220 may be less than a width in the first direction D1 of the bottom surface 283_B of the third conductive part 283. The first part 222 of the first connection conductive structure 220 may be surrounded by the second dielectric layer 157 of the first dielectric structure 150. The second part 221 of the first connection conductive structure 220 may be surrounded by the first substrate 100 and the first dielectric layer 210.

The first connection conductive structure 220 may be located at the same level as that of the transfer gate TG. The bottom surface 222_B of the first part 222 included in the first connection conductive structure 220 may be located at the same level as that of a bottom surface of the transfer gate TG. The top surface 221_T of the second part 221 included in the first connection conductive structure 220 may be located at the same level as that of a top surface of the transfer gate TG. The width in the first direction D1 of the first part 222 included in the first connection conductive structure 220 may be greater than the width in the first direction D1 of the second connection conductive structure 230.

The second dielectric layer 157 may include a part interposed between the first parts 222 of the first connection conductive structures 220. The sixth interlayer dielectric layer 156 may include a part interposed between the first parts 222 of the first connection conductive structures 220.

A recess RS may be defined on the pad zone PDR of the first substrate 100. The recess RS may be defined as being recessed from the top surface 101 of the first substrate 100. The recess RS may be connected to the top surface 101 of the first substrate 100. The recess RS may be located at a lower level than that of the top surface 101 of the first substrate 100. A bottom surface and a sidewall of the recess RS may be defined by surfaces of the first substrate 100.

Holes HO may be defined on the pad zone PDR of the first substrate 100. The holes HO may be connected to the recess RS. The holes HO may be located at a lower level than that of the recess RS. A sidewall of the hole HO may be defined by the surface of the first substrate 100. A bottom surface of the hole HO may be defined by the surface of the first substrate 100, the top surface 221_T of the second part 221 included in the first connection conductive structure 220, and the top surface 210_T of the first dielectric layer 210. A width in the first direction D1 of the hole HO may be less than a width in the first direction D1 of the recess RS.

The conductive structure 280 may include a first conductive part 281, a second conductive part 282 (i.e., a conductive layer), and third conductive parts 283 (i.e., conductive vias). The second conductive part 282 may be provided in the recess RS. The second conductive part 282 may be located at a lower level than that of the top surface 101 of the first substrate 100. The first conductive part 281 may be located at a higher level than that of the top surface 101 of the first substrate 100. The third conductive part 283 may completely fill the hole HO. The third conductive parts 283 may be connected to the second conductive part 282. The first, second, and third conductive parts 281, 282, and 283 are explained as being distinguished from each other in the interest of convenience of description, but may be connected to have a single unitary structure without any boundary therebetween.

The first material layer 271 may be provided between the first substrate 100 and the second material layer 272. The first material layer 271 may include a first part P1 in contact with the top surface 101 of the first substrate 100 and a second part P2 in the recess RS. The second material layer 272 may include a first part P3 on the first part P1 of the first material layer 271 and a second part P4 in the recess RS.

The first conductive part 281 may be provided on the first part P3 of the second material layer 272. The second conductive part 282 may be provided in the second part P4 of the second material layer 272. A sidewall and a bottom surface 282_B of the second conductive part 282 may be in contact with the second part P4 of the second material layer 272. The third conductive part 283 may penetrate the second part P2 of the first material layer 271 and the second part P4 of the second material layer 272. A sidewall 283_S of the third conductive part 283 may be in contact with the second part P4 of the second material layer 272 and the second part P2 of the first material layer 271. The first material layer 271 and the second material layer 272 may separate the first conductive part 281 and the second conductive part 282 from the first substrate 100. The sidewall 283_S of the third conductive part 283 may be in contact with the pad zone PDR of the first substrate 100.

The conductive structure 280 may surround the pad 290. The first conductive part 281 may be in contact with a sidewall of the pad 290. The second conductive part 282 may be in contact with the sidewall and a bottom surface 290_B of the pad 290. The third conductive part 283 may protrude from the bottom surface 282_B of the second conductive part 282 toward the bottom surface 102 of the first substrate 100. The third conductive part 283 may be spaced apart from the pad 290.

The third conductive parts 283 may be arranged spaced apart from each other in the first direction D1. The second part P2 of the first material layer 271 and the second part P4 of the second material layer 272 may each include a part interposed between the third conductive parts 283. The third conductive part 283 may overlap the first connection conductive structure 220, the second connection conductive structure 230, and the pad 290 in the third direction D3. A width in the first direction D1 of the third conductive part 283 may decrease with decreasing distance from the bottom surface 102 of the first substrate 100. The width in the first direction D1 of the third conductive part 283 may decrease with decreasing distance from the top surface 221_T of the second part 221 included in the first connection conductive structure 220.

A length in the third direction D3 of the third conductive part 283 may be greater than a length in the third direction D3 of each of the first connection conductive structure 220 and of the second connection conductive structure 230. The third conductive part 283 may be disposed between the second conductive part 282 and the first connection conductive structure 220. The width in the first direction D1 of the third conductive part 283 may be less than the width in the first direction D1 of the third connection conductive structure 240.

The pad 290 may overlap the pad zone PDR in the third direction D3. A distance in the third direction D3 between the bottom surface 282_B of the second conductive part 282 and the bottom surface 102 of the first substrate 100 may be less than a distance in the third direction D3 between the bottom surface 290_B of the pad 290 and the bottom surface 102 of the first substrate 100. A distance in the third direction D3 between the bottom surface 283_B of the third conductive part 283 and the bottom surface 102 of the first substrate 100 may be less than the distance in the third direction D3 between the bottom surface 282_B of the second conductive part 282 and the bottom surface 102 of the first substrate 100.

The bottom surface 290_B of the pad 290, the bottom surface 282_B of the second conductive part 282, and the bottom surface 283_B of the third conductive part 283 may be disposed between the top surface 101 and the bottom surface 102 of the first substrate 100.

In an image sensor according to some embodiments, the pad 290 and the third connection conductive structure 240 may be connected through the conductive structure 280, the first connection conductive structure 220, and the second connection conductive structure 230. Thus, the third conductive part 283, the first connection conductive structure 220, and the second connection conductive structure 230 may have their relatively large lengths and improved reliability.

In an image sensor according to some embodiments, as the third conductive part 283, the first connection conductive structure 220, and the second connection conductive structure 230 overlap the pad 290 in the third direction D, a minimized space may be provided for a structure that electrically connects the third connection conductive structure 240 and the pad 290 to each other, and the image sensor may become minimum in size.

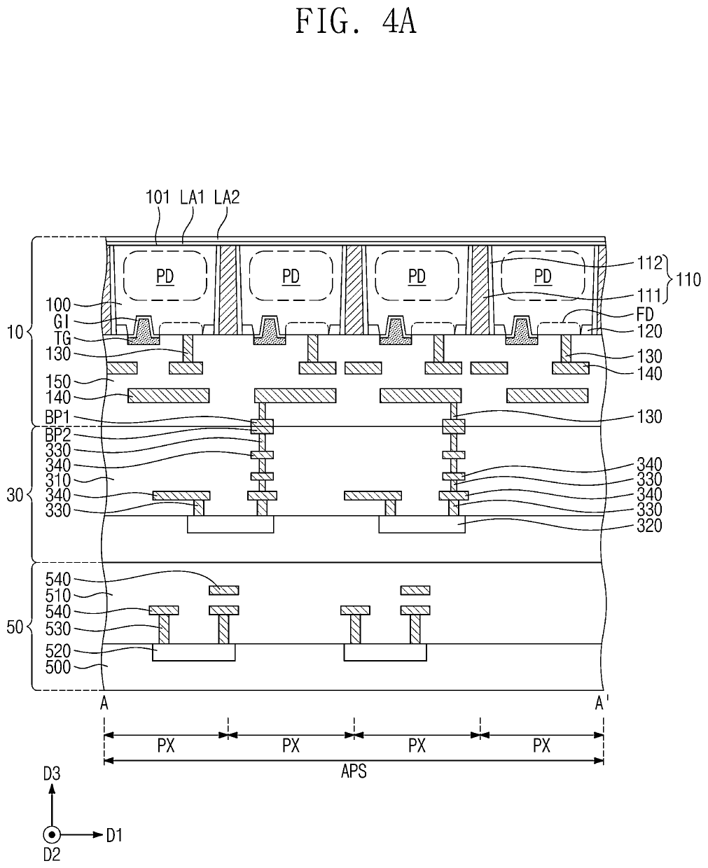

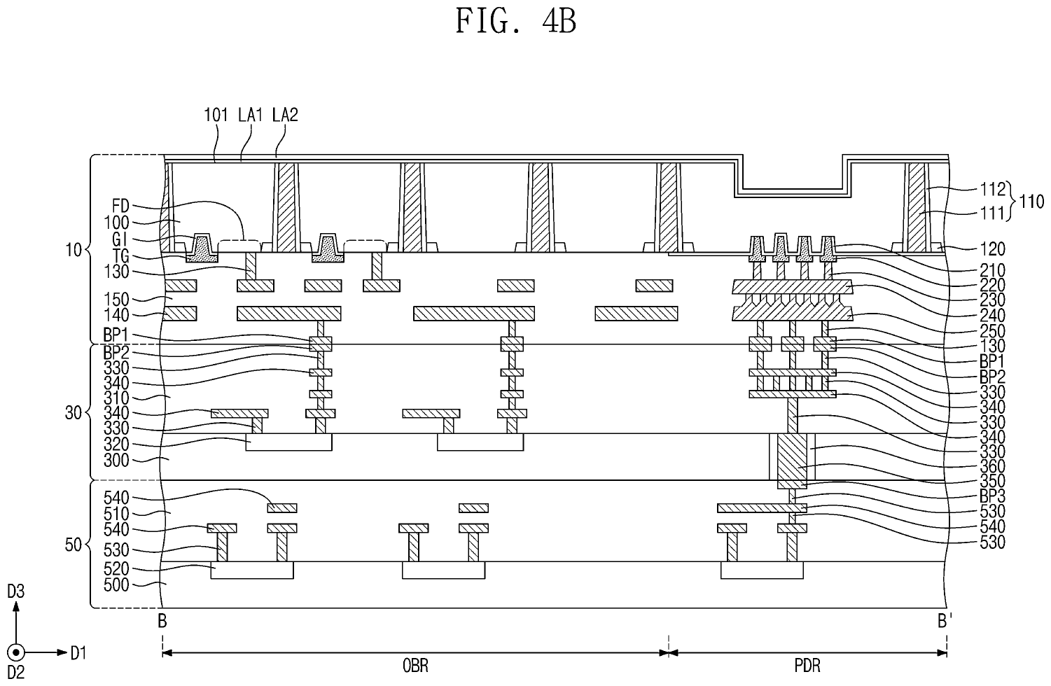

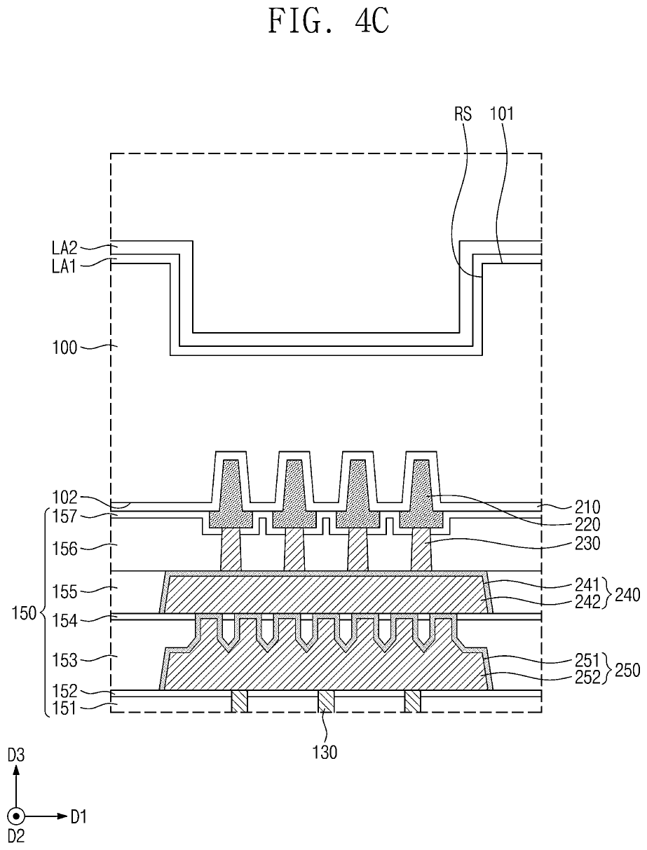

FIGS. 4A, 4B, 4C, 5, and 6 illustrate diagrams showing a method of fabricating an image sensor depicted in FIGS. 3A to 3D. FIG. 4A may correspond to FIG. 3B. FIG. 4B may correspond to FIG. 3C. FIGS. 4C, 5, and 6 may correspond to FIG. 3D.

Referring to FIGS. 4A, 4B, and 4C, a sub-chip 30 may be formed on a circuit chip 50.

A sensor chip 10 may be formed. The formation of the sensor chip 10 may include forming a pixel isolation pattern 110 to penetrate a first substrate 100, forming a photoelectric conversion region PD in a pixel array zone APS of the first substrate 100, and forming on a bottom surface 102 of the first substrate 100 a first dielectric layer 210, a floating diffusion region FD, a gate dielectric layer GI, a transfer gate TG, a first connection conductive structure 220, a second connection conductive structure 230, a third connection conductive structure 240, a fourth connection conductive structure 250, a first contact 130, a first conductive line 140, a first bonding pad BP1, and a first dielectric structure 150.

The sensor chip 10 may be hybrid bonded to the sub-chip 30. A top surface 101 of the first substrate 100 may be etched to form a recess RS. A first preliminary layer LA1 may be formed on the first substrate 100. A second preliminary layer LA2 may be formed on the first preliminary layer LA1. A portion of each of the first and second preliminary layers LA1 and LA2 may be provided in the recess RS.

The first preliminary layer LA1 may include a dielectric material. For example, the first preliminary layer LA1 may include aluminum oxide. In some embodiments, the second preliminary layer LA2 may be a multiple layer including a plurality of layers. For example, the second preliminary layer LA2 may include a first layer including hafnium oxide, a second layer including silicon oxide, a third layer including silicon nitride, and a fourth layer including hafnium oxide.

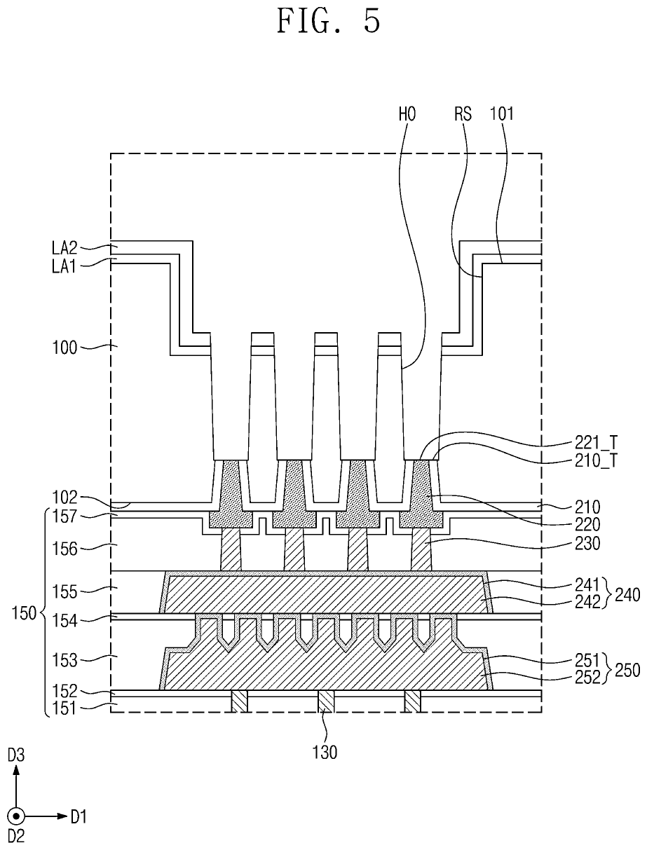

Referring to FIG. 5, holes HO may be formed. The first preliminary layer LA1, the second preliminary layer LA2, and the first substrate 100 may be etched through the recess RS, thereby forming the holes HO. The hole HO may expose a top surface 221_T of the first connection conductive structure 220 and a top surface 210_T of the first dielectric layer 210.

A length in a third direction D3 of the hole HO may be less than a length may be less than a length in the third direction D3 of the first substrate 100.

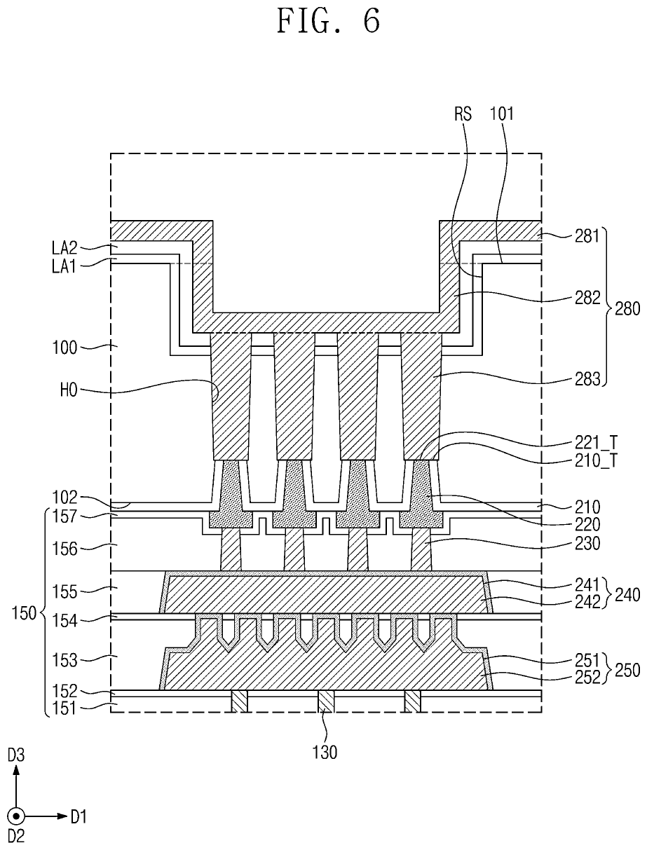

Referring to FIG. 6, a conductive structure 280 may be formed. The conductive structure 280 may be formed by, for example, a deposition process. A third conductive part 283 of the conductive structure 280 may completely fill the hole HO. In some embodiments, the third conductive part 283 of the conductive structure 280 may fill only a portion of the hole HO.

Referring to FIGS. 3A to 3D, the first preliminary layer LA1 may be divided into a first protective layer 161 and a first material layer 271. The second preliminary layer LA2 may be divided into a fixed charge layer 162 and a second material layer 272. A fence pattern 164 and a light-shield layer 265 may be formed. In some embodiments, the formation of the fence pattern 164, the light-shield layer 265, and the conductive structure 280 may include forming a preliminary conductive layer and dividing the preliminary conductive layer into the fence pattern 164, the light-shield layer 265, and the conductive structure 280. A connection contact 266 may be formed on the light-shield layer 265.

A second protective layer 163 and a third protective layer 261 may be formed. A color filter CF and a filtering layer 262 may be formed. There may be formed a lens layer 170, a coating layer 171, a first cover layer 263, and a second cover layer 264. In some embodiments, the lens layer 170 and the first cover layer 263 may be formed at the same time. The coating layer 171 and the second cover layer 264 may be formed at the same time.

In a method of fabricating an image sensor according to some embodiments, as the hole HO exposes the first connection conductive structure 220 that does not include copper, there may be a relative improvement in oxidation of conductive structures electrically connected to the pad 290.

In a method of fabricating an image sensor according to some embodiments, as the hole HO is completely filled with the third conductive part 283, the hole HO may be prevented from being filled with a process material for forming the color filter CF.

In a method of fabricating an image sensor according to some embodiments, as the hole HO has a length less than that of the first substrate 100, there may be an improvement in process margin for a process forming the hole HO.

In a method of fabricating an image sensor according to some embodiments, only the first preliminary layer LA1, the second preliminary layer LA2, and the first substrate 100 may be etched to form the hole HO, and thus a fabrication process may be simplified.

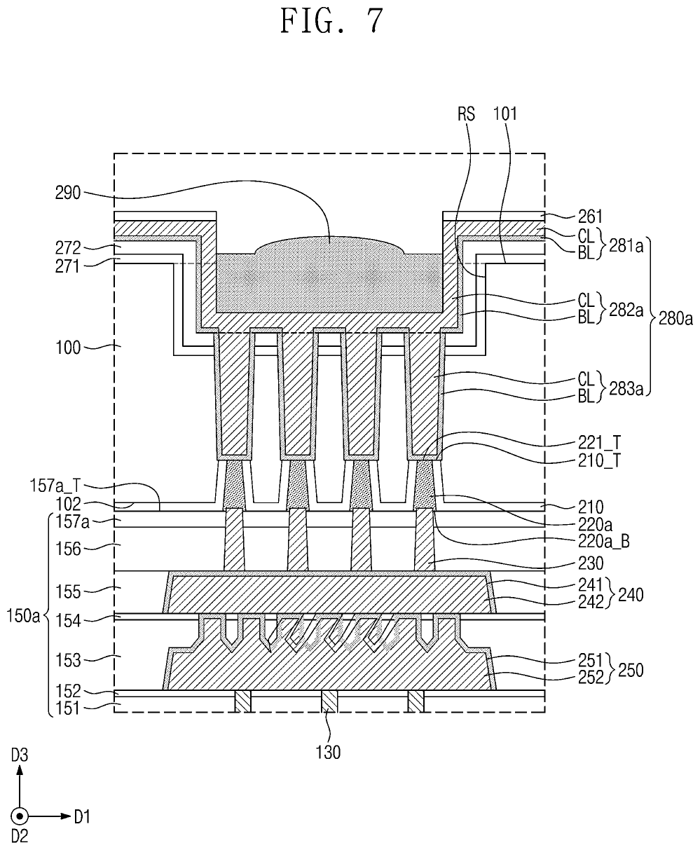

FIG. 7 illustrates an enlarged cross-sectional view showing an image sensor according to some embodiments. Except the following description, an image sensor of FIG. 7 may be similar to the image sensor of FIGS. 3A to 3D.

Referring to FIG. 7, a first connection conductive structure 220a may be surrounded by the first dielectric layer 210. A bottom surface 220a_B of the first connection conductive structure 220a may be in contact with a top surface 157a_T of a second dielectric layer 157a included in a first dielectric structure 150a. The second dielectric layer 157a may have a flat top surface 157a_T and a flat bottom surface.

Each of a first conductive part 281a, a second conductive part 282a, and a third conductive part 283a of a conductive structure 280a may include a barrier layer BL and a metal layer CL. The barrier layer BL and the metal layer CL may include different conductive materials from each other. For example, the metal layer CL may include tungsten, and the barrier layer BL may include titanium.

The barrier layers BL of the first, second, and third conductive parts 281a, 282a, and 283a may be connected to have a single unitary structure without any boundary therebetween. The metal layers CL of the first, second, and third conductive parts 281a, 282a, and 283a may be connected to have a single unitary structure without any boundary therebetween.

The metal layers CL of the third conductive part 283a may be spaced apart from each other in the first direction D1. The metal layers CL of the third conductive part 283a may overlap the pad 290 in the third direction D3.

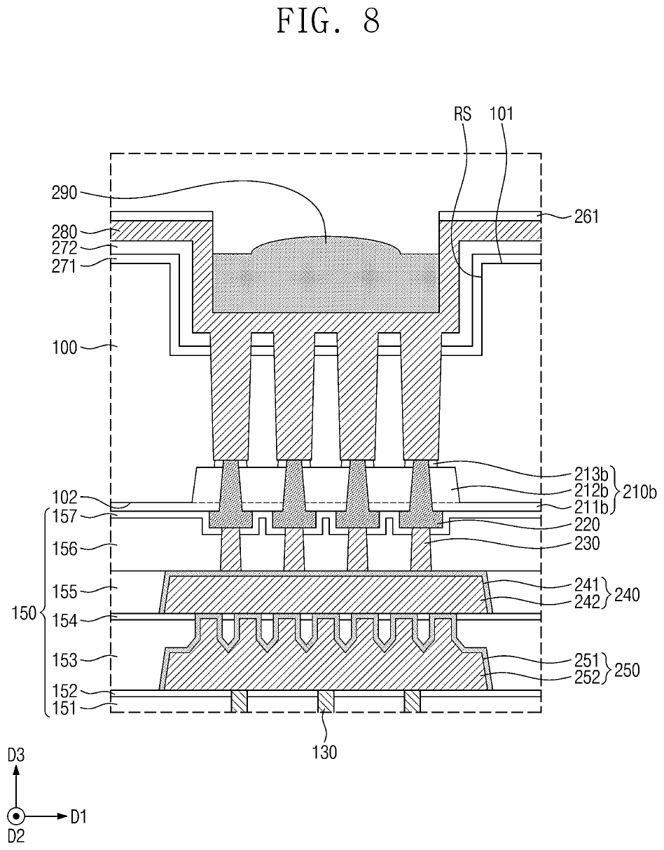

FIG. 8 illustrates an enlarged cross-sectional view showing an image sensor according to some embodiments. Except the following description, an image sensor of FIG. 8 may be similar to the image sensor of FIGS. 3A to 3D.

Referring to FIG. 8, a first dielectric layer 210b may include a first part 211b, a second part 212b on the first part 211b, and third parts 213b on the second part 212b.

The first part 211b of the first dielectric layer 210b may be in contact with the second dielectric layer 157. The second part 212b of the first dielectric layer 210b may surround a plurality of first connection conductive structures 220. The third parts 213b of the first dielectric layer 210b may correspondingly surround the first connection conductive structures 220.

A width in the first direction D1 of the second part 212b included in the first dielectric layer 210b may be greater than a sum of widths in the first direction D1 of the first connection conductive structures 220. The width in the first direction D1 of the second part 212b included in the first dielectric layer 210b may be greater than a sum of widths in the first direction D1 of the third parts 213b included in the first dielectric layer 210b.

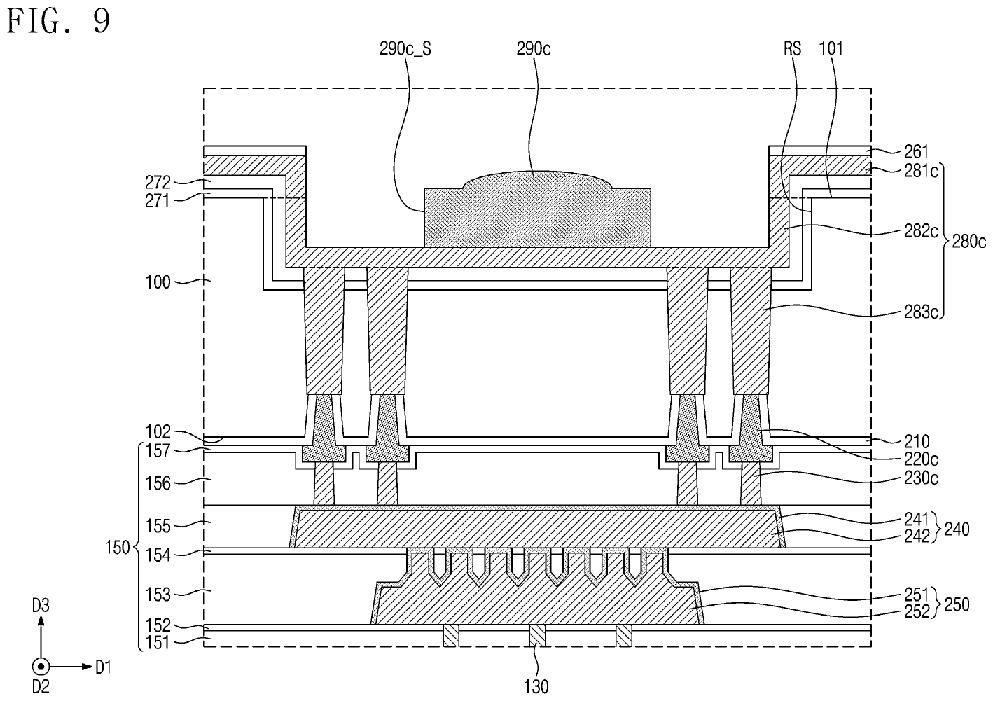

FIG. 9 illustrates an enlarged cross-sectional view showing an image sensor according to some embodiments. Except the following description, an image sensor of FIG. 9 may be similar to the image sensor of FIGS. 3A to 3D.

Referring to FIG. 9, a sidewall 290c_S of a pad 290c may be spaced apart from a conductive structure 280c. The sidewall 290c_S of the pad 290c may be spaced apart from a first conductive part 281c and a second conductive part 282c of the conductive structure 280c.

The pad 290c may be disposed between third conductive parts 283c of the conductive structure 280c. The third conductive parts 283c may be disposed on opposite sides of the pad 290c. The pad 290c may be disposed between the third conductive parts 283c on one side of the pad 290c and the third conductive parts 283c another side of the pad 290c.

The pad 290c may be disposed between first connection conductive structures 220c. The first connection conductive structures 220c may be disposed on opposite sides of the pad 290c. The pad 290c may be disposed between the first connection conductive structures 220c on one side of the pad 290c and the first connection conductive structures 220c on another side of the pad 290c.

The pad 290c may be disposed between second connection conductive structures 230c. The second connection conductive structures 230c may be disposed on opposite sides of the pad 290c. The pad 290c may be disposed between the second connection conductive structures 230c on one side of the pad 290c and the second connection conductive structures 230c on another side of the pad 290c.

None of the third conductive parts 283c, the first connection conductive structures 220c, and the second connection conductive structures 230c may overlap the pad 290c in the third direction D3. The third conductive parts 283c, the first connection conductive structures 220c, and the second connection conductive structures 230c may be spaced apart in the first direction D1 from the pad 290c.

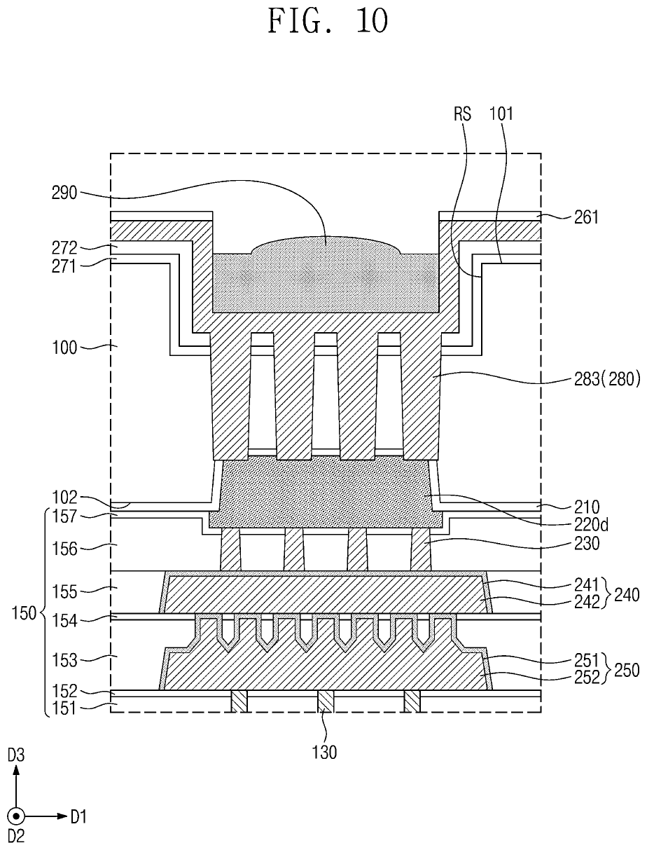

FIG. 10 illustrates an enlarged cross-sectional view showing an image sensor according to some embodiments. Except the following description, an image sensor of FIG. 10 may be similar to the image sensor of FIGS. 3A to 3D.

Referring to FIG. 10, one first connection conductive structure 220d may be provided between a plurality of third conductive parts 283 and a plurality of second connection conductive structures 230. The plurality of third conductive parts 283 may be in contact with the first connection conductive structure 220d. The plurality of second connection conductive structures 230 may be in contact with the first connection conductive structure 220d.

In some embodiments, the conductive structure 280 may include one third conductive part 283. In some embodiments, the third connection conductive structure 240 may be connected to the second connection conductive structure 230.

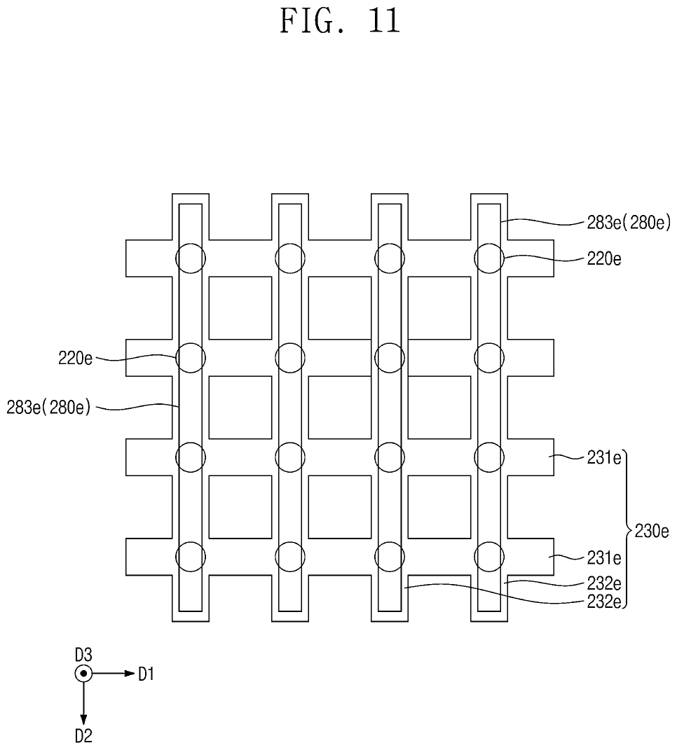

FIG. 11 illustrates a plan view showing a conductive layer and connection conductive structures of an image sensor according to some embodiments. Except the following description, an image sensor of FIG. 11 may be similar to the image sensor of FIGS. 3A to 3D.

Referring to FIG. 11, a third conductive part 283e of a conductive structure 280e may have a bar shape that extends in the second direction D2. A first connection conductive structure 220e may have a cylindrical shape. A second connection conductive structure 230e may include first parts 231e that extend in the first direction D1 and second parts 232e that extend in the second direction D2. The second connection conductive structure 230e may have a mesh shape in which the first parts 231e intersect the second parts 232e.

In some embodiments, the third conductive part 283e may have a cylindrical or mesh shape. The first connection conductive structure 220e may have a bar or mesh shape. The second connection conductive structure 230e may have a cylindrical or bar shape.

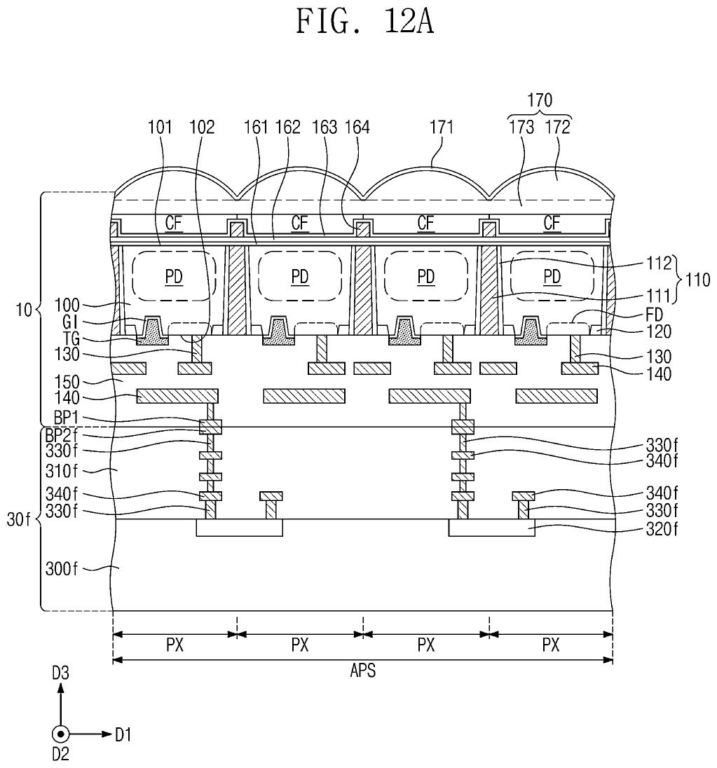

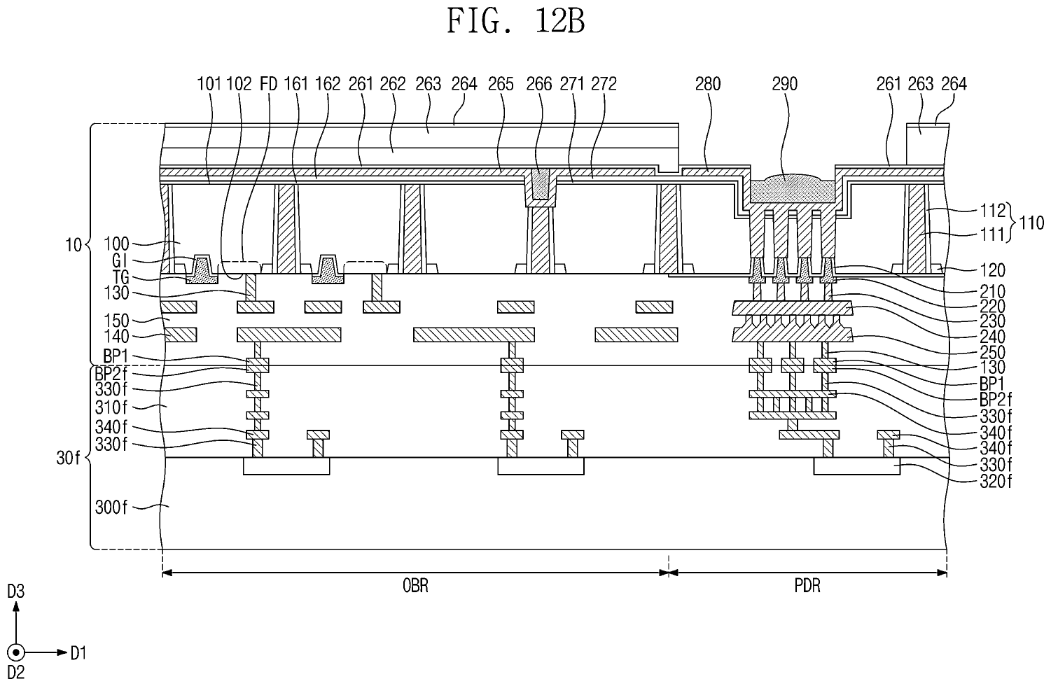

FIGS. 12A and 12B illustrate cross-sectional views showing an image sensor according to some embodiments. Except the following description, an image sensor of FIGS. 12A and 12B may be similar to the image sensor of FIGS. 3A to 3D.

Referring to FIGS. 12A and 12B, the sensor chip 10 may be hybrid bonded to a circuit chip 30f. The circuit chip 30f may include a second substrate 300f, an electronic element 320f, a second contact 330f, a second conductive line 340f, a second bonding pad BP2f, and a second dielectric structure 310f. The electronic element 320f may include at least one selected from an analog-digital converter, a memory circuit, and a logic circuit. The second bonding pad BP2f may be in contact with the first bonding pad BP1. The second dielectric structure 310f may be in contact with the first dielectric structure 150.

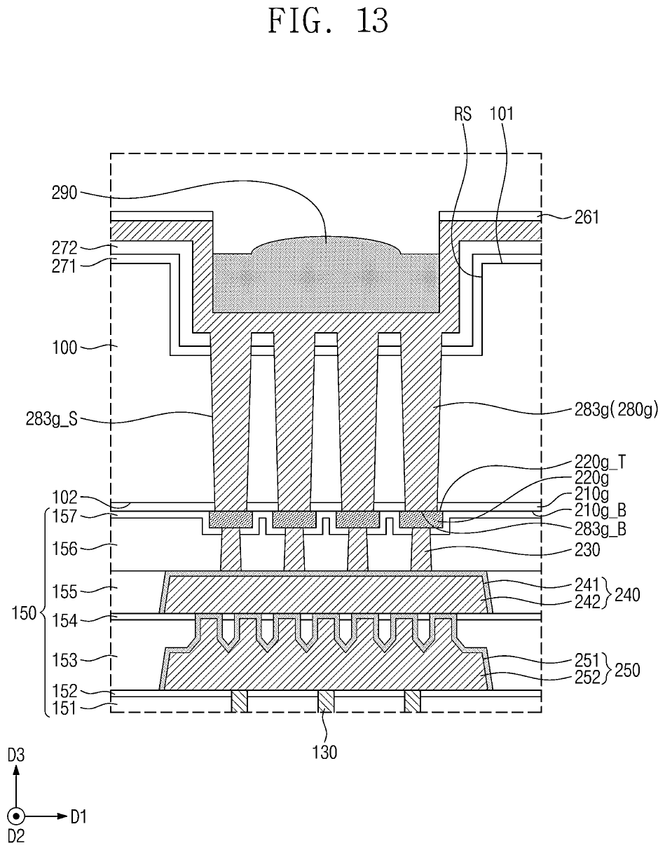

FIG. 13 illustrates an enlarged cross-sectional view showing an image sensor according to some embodiments. Except the following description, an image sensor of FIG. 13 may be similar to the image sensor of FIGS. 3A to 3D.

Referring to FIG. 13, a third conductive part 283g of a conductive structure 280g may penetrate the bottom surface 102 of the first substrate 100. The third conductive part 283g of the conductive structure 280g may have a bottom surface 283g_B in contact with a top surface 220g_T of a first connection conductive structure 220g. A first dielectric layer 210g may be in contact with the bottom surface 102 of the first substrate 100, a sidewall 283g_S of the third conductive part 283g, and the top surface 220g_T of the first connection conductive structure 220g. A bottom surface 210g_B of the first dielectric layer 210g may be in contact with the top surface 220g_T of the first connection conductive structure 220g.

The first dielectric layer 210g may have a flat bottom surface 210g_B and a flat top surface. The third conductive part 283g may penetrate the first dielectric layer 210g.

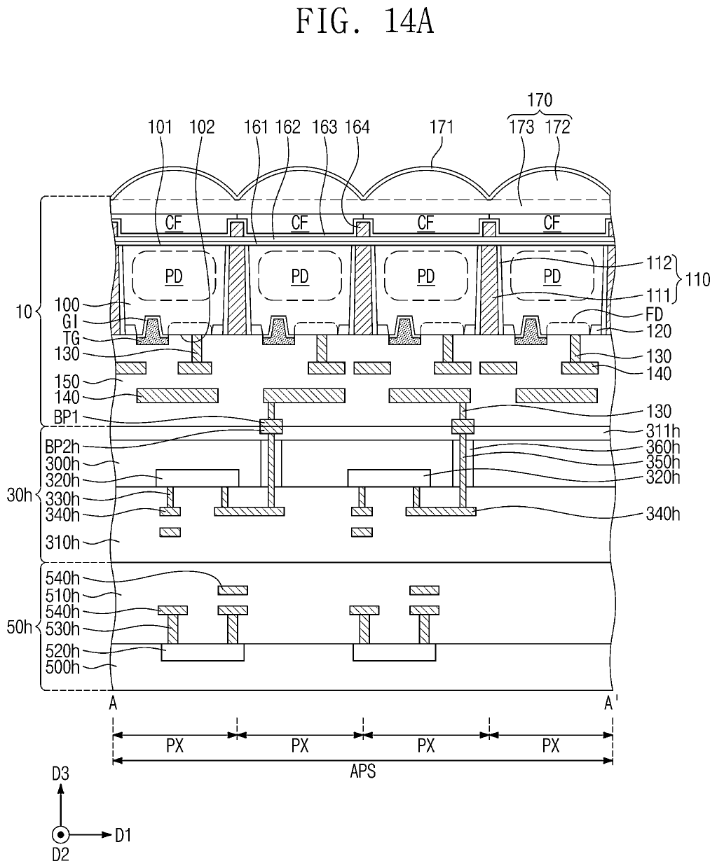

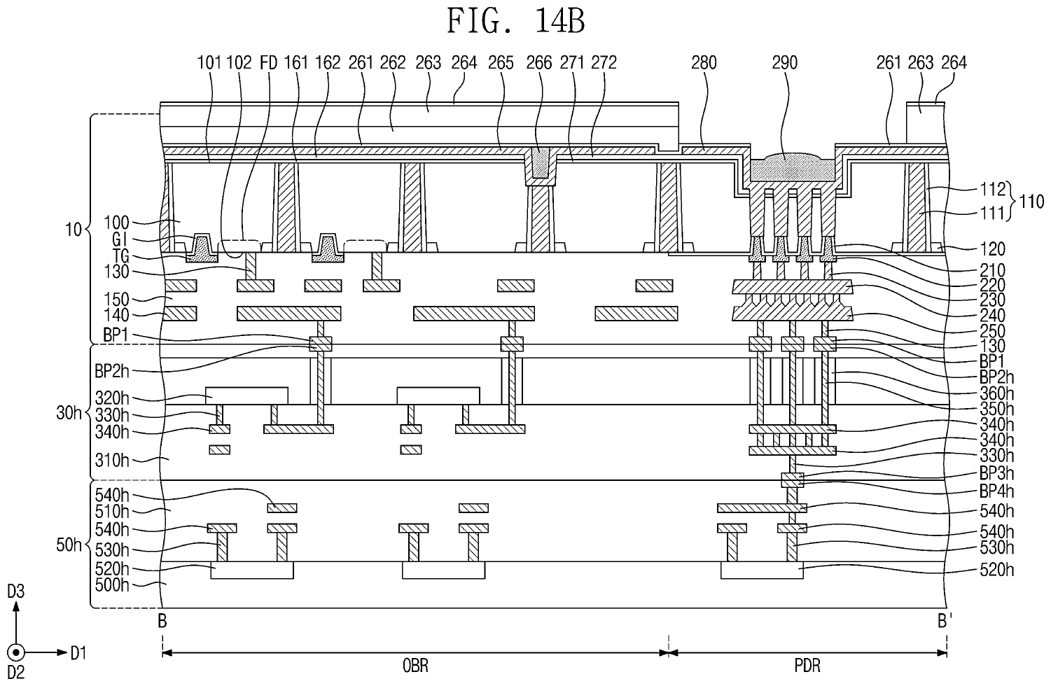

FIGS. 14A and 14B illustrate cross-sectional views showing an image sensor according to some embodiments. Except for that discussed below, an image sensor according to FIGS. 14A and 14B may be substantially identical or similar to the image sensor according to FIGS. 3A to 3D.

Referring to FIGS. 14A and 14B, a sub-chip 30h may include a second substrate 300h, a second dielectric structure 310h, a third dielectric structure 311h, first electronic elements 320h, second contacts 330h, second conductive lines 340h, through vias 350h, spacers 360h, second bonding pads BP2h, and a third bonding pad BP3h.

The first electronic elements 320h may be provided on a bottom surface of the second substrate 300h. The second dielectric structure 310h may cover the first electronic elements 320h. The second dielectric structure 310h may be in contact with the bottom surface of the second substrate 300h.

The third dielectric structure 311h may be in contact with a top surface of the second substrate 300h. The second substrate 300h may be provided between the second and third dielectric structures 310h and 311h. The third dielectric structure 311h may include a dielectric material. In some embodiments, the third dielectric structure 311h may be a multi-layered structure including a plurality of dielectric layers.

The second bonding pads BP2h may be provided in the third dielectric structure 311h. A top surface of the third dielectric structure 311h may be in contact with a bottom surface of the first dielectric structure 150. A top surface of the second bonding pad BP2h may be in contact with a bottom surface of the first bonding pad BP.

The spacer 360h may penetrate in the third direction D3 through the second substrate 300h. The spacer 360h may include a dielectric material. The through via 350h may penetrate in the third direction D3 through the second substrate 300h and the spacer 360h. The through via 350h may be connected to the second bonding pad BP2h and the second conductive line 340h. The through via 350h may include a conductive material different from that of the second bonding pad BP2h. For example, through via 350h may include tungsten.

The third bonding pad BP3h may be provided in the second dielectric structure 310h. The third bonding pad BP3h may be connected to the second contact 330h.

A circuit chip 50h may include a third substrate 500h, a fourth dielectric structure 510h, second electronic elements 520h, third contacts 530h, third conductive lines 540h, and a fourth bonding pad BP4h.

The fourth bonding pad BP4h may be connected to the third bonding pad BP3h and the third contact 530h. A top surface of the fourth bonding pad BP4h may be in contact with a bottom surface of the third bonding pad BP3h. A bottom surface of the second dielectric structure 310h may be in contact with a top surface of the fourth dielectric structure 510h.

In an image sensor according to some embodiments of the present inventive concepts, a minimized space may be provided for a structure electrically connected to a pad, and the image sensor may become minimum in size.

In a method of fabricating an image sensor according to some embodiments of the present inventive concepts, a process for forming a hole that completely penetrates a substrate may be omitted to improve a process margin.

It will be understood by those skilled in the art that the present inventive concepts may be implemented in other specific forms without changing its technical spirit or essential features. The above disclosed embodiments should thus be considered illustrative and not restrictive. Moreover, the embodiments discussed above may be combined with each other.

What is claimed is:

1. An image sensor comprising:
a substrate that includes a pixel array zone and a pad zone;
a microlens that overlaps the pixel array zone;
a pad that overlaps the pad zone; and
a conductive structure that surrounds the pad,
wherein the conductive structure includes:
a conductive layer in contact with a bottom surface of the pad; and
a conductive via that extends from a bottom surface of the conductive layer toward a bottom surface of the substrate,
wherein a material of the conductive layer is the same as a material of the conductive via,
wherein a distance between the bottom surface of the substrate and a bottom surface of the conductive via is less than a distance between the bottom surface of the substrate and the bottom surface of the conductive layer,
wherein the distance between the bottom surface of the substrate and the bottom surface of the conductive layer is less than a distance between the bottom surface of the substrate and the bottom surface of the pad, and
wherein the bottom surface of the pad and the bottom surface of the conductive layer are between the bottom surface of the substrate and a top surface of the substrate.

2. The image sensor of claim 1, further comprising:
a connection conductive structure that penetrates the bottom surface of the substrate,
wherein the bottom surface of the conductive via is in contact with a top surface of the connection conductive structure.

3. The image sensor of claim 2, further comprising:
a first dielectric layer in contact with a sidewall of the connection conductive structure, the bottom surface of the substrate, and the bottom surface of the conductive via.

4. The image sensor of claim 2,
wherein the connection conductive structure includes a first part and a second part on the first part,
wherein a maximum width of the second part of the connection conductive structure is less than a maximum width of the first part of the connection conductive structure, and
wherein the second part of the connection conductive structure has a decreasing width from the bottom surface of the conductive via toward the pad.

5. The image sensor of claim 2,
wherein the connection conductive structure includes polysilicon.

6. The image sensor of claim 1,
wherein the pad zone of the substrate defines a recess and a hole,
wherein the recess is connected to the top surface of the substrate,
wherein the hole is connected to the recess,
wherein a width of the hole is less than a width of the recess,
wherein the conductive layer is in the recess, and
wherein the conductive via completely fills the hole.

7. The image sensor of claim 1,
wherein the conductive layer is spaced apart from the substrate, and
wherein a sidewall of the conductive via is in contact with the substrate.

8. An image sensor comprising:
a substrate that includes a pixel array zone and a pad zone;
a microlens that overlaps the pixel array zone;
a pad that overlaps the pad zone;
a conductive structure that surrounds the pad; and
a first connection conductive structure electrically connected to the conductive structure,
wherein the conductive structure includes:
a conductive layer in contact with a bottom surface of the pad; and
a conductive via that extends from a bottom surface of the conductive layer toward a bottom surface of the substrate,
wherein a bottom surface of the conductive via is in contact with a top surface of the first connection conductive structure, and
wherein a sidewall of the conductive via is in contact with the substrate.

9. The image sensor of claim 8,
wherein the conductive via has a decreasing width from the top surface of the first connection conductive structure toward the pad.

10. The image sensor of claim 8,
wherein a width of the bottom surface of the conductive via is greater than a width of the top surface of the first connection conductive structure.

11. The image sensor of claim 8,
wherein the first connection conductive structure includes a first part and a second part on the first part,
wherein a maximum width of the second part of the first connection conductive structure is less than a maximum width of the first part of the first connection conductive structure, and
wherein the image sensor further comprises:
a first dielectric layer in contact with a sidewall of the second part of the first connection conductive structure and a top surface of the first part of the first connection conductive structure; and
a second dielectric layer in contact with a sidewall of the first part of the first connection conductive structure.

12. The image sensor of claim 11, further comprising:
a second connection conductive structure that penetrates the second dielectric layer and contacts the first connection conductive structure.

13. The image sensor of claim 11,
wherein the substrate includes a photoelectric conversion region,
wherein the image sensor further comprises a transfer gate that overlaps the photoelectric conversion region,
wherein a top surface of the first connection conductive structure is at the same level as a top surface of the transfer gate, and
wherein a bottom surface of the first connection conductive structure is at the same level as a bottom surface of the transfer gate.

14. The image sensor of claim 8,
wherein the first connection conductive structure penetrates the bottom surface of the substrate,
wherein the image sensor further comprises:
a second connection conductive structure in contact with the first connection conductive structure;
a third connection conductive structure in contact with the second connection conductive structure; and
a dielectric structure that surrounds the second connection conductive structure and the third connection conductive structure,
wherein a width of the third connection conductive structure is greater than a width of the second connection conductive structure, a width of the first connection conductive structure, and a width of the conductive via, and
wherein the second connection conductive structure includes a conductive material different from a conductive material of the third connection conductive structure.

15. The image sensor of claim 14,
wherein the third connection conductive structure includes copper,
wherein the second connection conductive structure includes tungsten, and
wherein the first connection conductive structure includes polysilicon.

16. The image sensor of claim 8, further comprising:
a first material layer in contact with the bottom surface of the conductive layer and the sidewall of the conductive via,
wherein the first material layer includes a dielectric material, and
wherein the conductive via penetrates the first material layer.

17. The image sensor of claim 16, further comprising:
a second material layer between the first material layer and the substrate,
wherein the second material layer includes a dielectric material different from the dielectric material of the first material layer,
wherein the sidewall of the conductive via is in contact with the second material layer, and
wherein the conductive via penetrates the second material layer.

18. The image sensor of claim 8,
wherein the conductive via is provided in plural so that a plurality of conductive vias extends from the bottom surface of the conductive layer toward the bottom surface of the substrate,
wherein the plurality of conductive vias are spaced apart from each other,
wherein the pad, when viewed in a plan view, is disposed on a region between two adjacent conductive vias of the plurality of conductive vias.

19. An image sensor comprising:
a first substrate that includes a pixel array zone and a pad zone, wherein the pixel array zone includes a photoelectric conversion region;
a color filter that overlaps the photoelectric conversion region;
a lens layer on the color filter;
a pad that overlaps the pad zone;
a conductive structure that surrounds the pad;
a second substrate spaced apart from the first substrate;
a first dielectric structure and a second dielectric structure that are in contact with each other between the first substrate and the second substrate;
a first bonding pad in the first dielectric structure;
a second bonding pad in the second dielectric structure and in contact with the first bonding pad; and
a first connection conductive structure and a second connection conductive structure that electrically connect the conductive layer to the first bonding pad,
wherein the conductive structure includes:
a conductive layer in contact with a bottom surface of the pad; and
a conductive via between the conductive layer and the first connection conductive structure,
wherein a material of the conductive layer is the same as a material of the conductive via,
wherein the second connection conductive structure is surrounded by the first dielectric structure, and
wherein the first connection conductive structure includes:
a first part surrounded by the first substrate; and
a second part surrounded by the first dielectric structure.

20. The image sensor of claim 19, further comprising:
a material layer that separates the conductive layer and the first substrate from each other,
wherein the conductive via penetrates the material layer.
